(19) United States
(12) Patent Application Publication
(10) Pub. No.: US 2005/0074046 A1
(43) Pub. Date: Apr. 7, 2005

(54) Light emitting device

(75) Inventor: Toshio Kasai, Tokyo (JP)

Correspondence Address: GREENBLUM & BERNSTEIN, P.L.C., 1950 ROLAND CLARKE PLACE, RESTON, VA, 20191, US

(73) Assignee: PENTAX Corporation, Tokyo (JP)

(21) Appl. No.: 10/954,291

(22) Filed: Oct. 1, 2004

(30) Foreign Application Priority Data
Oct. 3, 2003 (JP) 2003-345202

(51) Int. Cl. H01S 5/00

(52) U.S. Cl. 372/50; 372/36

(57) ABSTRACT

There is provided a light emitting device, which is provided with a light emitting element that emits light, a driving circuit that drives the light emitting device, and a package that accommodates the light emitting device and the driving circuit.

### BACKGROUND OF THE INVENTION

The present invention relates to a light emitting device such as a laser diode for emitting light.

A laser diode configured such that a laser diode chip and a monitoring photodiode are integrally accommodated in a metal or plastic package has been widely used. For example, such a laser diode is used in a laser scanning unit employed in a laser beam printer.

In the laser scanning unit, a control circuit board including a driving circuit for the laser diode chip and a processing circuit for processing a signal from the monitoring photodiode in the laser diode is mounted. In the following, the term “driving circuit” is used to represent a circuit including a circuit for driving the laser diode chip and the processing circuit for processing the signal from the monitoring photodiode.

The laser diode and the control circuit board are connected to each other through appropriate wirings. Since locating the control circuit board in the vicinity of the laser diode makes the size of the laser scanning unit large, the control circuit board is located away from the laser diode in the laser scanning unit.

Such an arrangement of the laser diode and the control circuit board is advantageous in regard to downsize of the laser scanning unit. However, such an arrangement may raise a problem that a ringing or overshoot arises on a driving signal for the laser diode chip because of a relatively long length of wirings between the laser diode and the control circuit board.

Japanese Patent Provisional Publication No. HEI 6-31980 discloses a configuration in which a semiconductor laser is mounted on a controller board including the driving circuit and the controller board is supported by a supporting member together with an optical system. Since the semiconductor laser is mounted on the controller board including the driving circuit, the length of wirings between the semiconductor laser and the driving circuit can be shortened.

However, in the above mentioned configuration, the semiconductor laser is connected to the driving circuit via a connection pattern on the controller board. This means that the length between the laser diode chip and the driving circuit can not be shortened to a length shorter than a lead of the package of the semiconductor laser.

For this reason, it may become difficult to drive the semiconductor laser under a suitable matching condition because of parasitic capacitance and resistance of the connection pattern between the laser diode chip in the package of the semiconductor laser and the driving circuit on the controller board.

In addition to the disadvantage indicated above, use of the configuration disclosed in the publication may cause a problem that the design for downsizing the laser scanning unit becomes difficult because the controller board is supported together with the optical system in the laser scanning unit.

### SUMMARY OF THE INVENTION

The present invention is advantageous in that it provides a light emitting device which is configured to improve output performance of light and to reduce its size.

According to an aspect of the invention, there is provided a light emitting device, which is provided with a light emitting element that emits light, a driving circuit that drives the light emitting element, and a package that accommodates the light emitting element and the driving circuit.

With this structure, it is possible to connect the driving circuit to the light emitting element by bonding wires. Therefore, parasitic capacitance and resistance of wiring between the light emitting device and the driving circuit can be decreased extremely, by which the output performance of laser light can be improved. The light emitting device can be downsized. Also, an apparatus employing the light emitting device can be downsized.

Optionally, the light emitting device may include a light receiving element that receives the light emitted by the light emitting element, the light receiving element being accommodated in the package.

Still optionally the driving circuit may include a processing circuit that processes a receiving signal generated by the light receiving element.

Still optionally, the driving circuit and the light receiving element may be integrally formed on a single semiconductor chip.

Still optionally, the light emitting device may include a mount on which the single semiconductor chip is mounted. In this case, the light emitted by the light emitting element includes monitoring light to be received by the light receiving element in the package. The mount is positioned in the package such that a central axis of the monitoring light is perpendicular to a top surface of the mount. The single semiconductor chip is mounted on the mount such that the single semiconductor chip is inclined with respect to the top surface of the mount.

In a particular case, the light emitting element may be mounted on the single semiconductor chip.

In a particular case, the driving circuit may be formed on a first semiconductor chip, and the light receiving element may be formed on a second semiconductor chip located in the package separately from the first semiconductor chip.

Optionally, the light emitting device may include a mount on which the first semiconductor chip and the second semiconductor chip are mounted. In this case, the light emitted by the light emitting element includes monitoring light to be received by the light receiving element in the package. The mount is positioned in the package such that a central axis of the monitoring light is perpendicular to a top surface of the mount. The second semiconductor chip is mounted on the mount such that the second semiconductor chip is inclined with respect to the top surface of the mount.

Still optionally, the light emitting element may be mounted on the second semiconductor chip.

Still optionally, the light emitting device may include a mount on which the first semiconductor chip and the second semiconductor chip are mounted.

Still optionally, the light emitting device may include a thermal insulation plate on which the first semiconductor chip and the second semiconductor chip are mounted.

In a particular case, the light emitting element, the light receiving element and the driving circuit may be located in the package separately with respect to each other.

In a particular case, the light emitting element may include a plurality of light emitting points.

In a particular case, the package may be formed as a metal package.

In a particular case, the package may be formed as a plastic package.

In a particular case, the package may be formed as a surface mount type package.

### BRIEF DESCRIPTION OF THE ACCOMPANYING DRAWINGS

FIG. 1 shows a configuration of a laser scanning unit employing a laser diode according to one of embodiments of the present invention;

FIG. 2 is a perspective view of a laser diode according a first embodiment of the invention;

FIG. 3 is an enlarged cross sectional view of the laser diode along a line A-A in FIG. 2;

FIG. 4 is a circuit diagram of a driver chip and a laser diode chip in the laser diode;

FIG. 5 is a cross sectional view of a laser diode according to a second embodiment of the invention;

FIG. 6 is a perspective view of a laser diode according to a third embodiment of the invention;

FIG. 7 is a cross sectional view of the laser diode along a line B-B in FIG. 6;

FIG. 8 is a cross sectional view of a laser diode according to a fourth embodiment;

FIG. 9 is a perspective view of a laser diode according to a fifth embodiment illustrating an internal configuration of the laser diode; and

FIG. 10 is a circuit diagram with regard to a photodiode and laser diode chips.

### DETAILED DESCRIPTION OF THE EMBODIMENTS

Hereinafter, embodiments according to the invention are described with reference to the accompanying drawings.

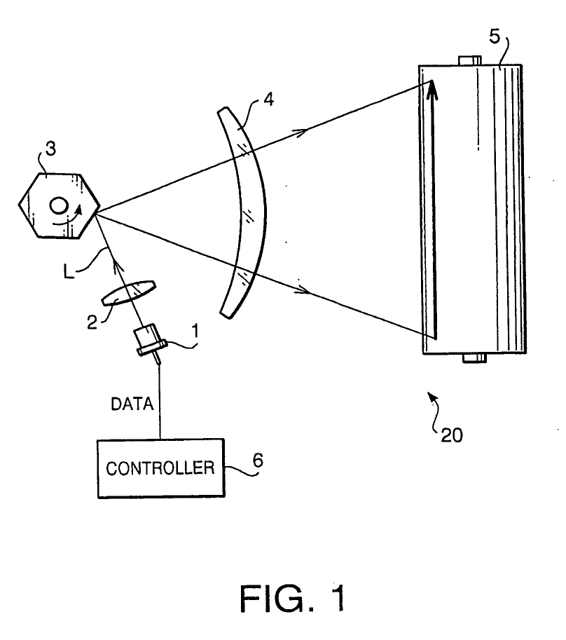

FIG. 1 shows a configuration of a laser scanning unit 20 employing a laser diode 1 according to one of the embodiments of the present invention. As described later, the laser diode 1 accommodates a laser diode chip and a driver chip including a driving circuit and a processing circuit.

As shown in FIG. 1, the laser scanning unit 20 includes the laser diode 1, a collimator lens 2, a polygonal mirror 3, an fθ lens 4 and a photoconductive drum 5. A laser beam emitted by the laser diode 1 is collimated by the collimator lens 2, and then incident on the polygonal mirror 3 rotating about its rotation axis. The polygonal mirror 3 dynamically deflects the laser beam in a predetermined angular range so that the laser beam is scanned on the photoconductive drum 5 in a main scanning direction.

The beam deflected by the polygonal mirror 3 passes through the fθ lens 4 which converges the incident laser beam onto the photoconductive drum 5 to form a beam spot scanning in the main scanning direction. The photoconductive drum 5 rotates about its rotational axis. That is, a scan target surface (a peripheral surface of the photoconductive drum 5) moves in an auxiliary scanning direction which is perpendicular to the main scanning direction on the scan target surface. With this structure, a two dimensional image can be formed on the photoconductive drum 5.

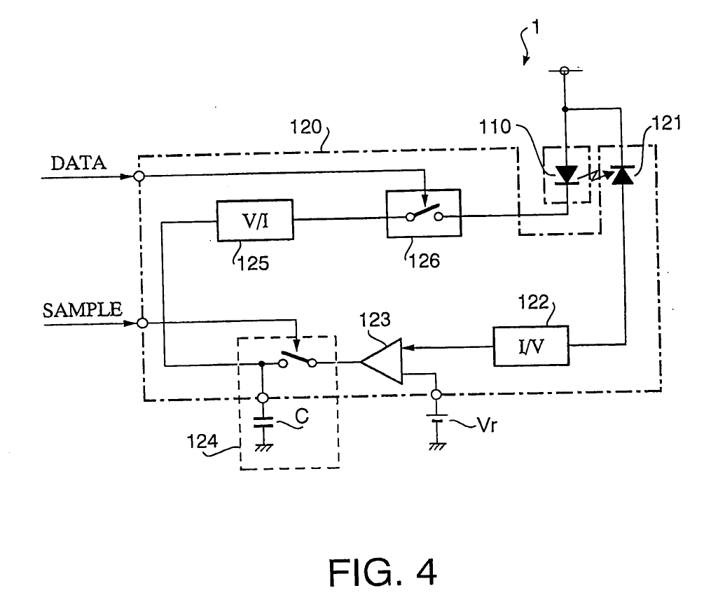

A controller 6 connected to the laser diode 1 supplies a data signal and a sample signal to the laser diode 1 (see FIG. 4). The data signal is used to on-off modulate current supplied to the laser diode chip in the laser diode 1, and the sample signal is used to adjust driving current for driving the laser diode chip. Since the control signals between the laser diode 1 and the controller 6 are not used to directly drive the laser diode chip, the controller 6 can be located at a position away from the laser diode 1 in an apparatus (e.g., a laser beam printer) employing the laser scanning unit 20. Specifically, the control signals are inputted to the driver chip 120 accommodated in the laser diode 1 (see FIG. 4).

First Embodiment

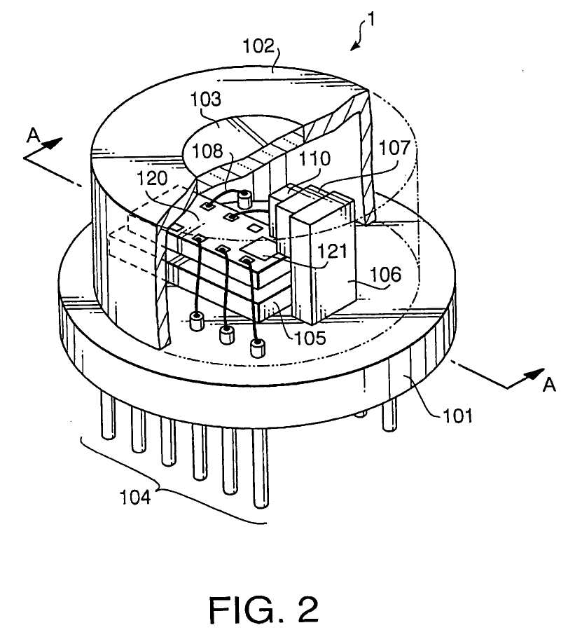

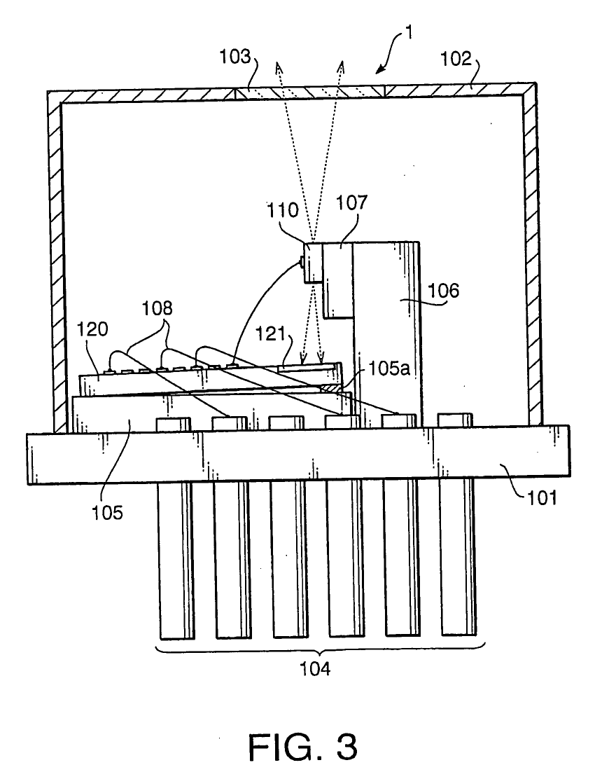

Hereafter, a laser diode according to a first embodiment of the invention will be described. FIG. 2 is a perspective view of the laser diode 1 according to the first embodiment of the invention. For illustration purpose of an internal configuration, a cap 102 is opened partially. FIG. 3 is an enlarged cross sectional view of the laser diode 1 along a line A-A in FIG. 2. As shown in FIGS. 2 and 3, the laser diode 1 is configured such that a laser diode chip 110 and a driver chip 120 are integrally mounted in a package.

Specifically, the laser diode 1 includes a circular stem 101 on which a mount 105 and a post 106 are fixed. On the stem 101, a cylindrical cap 102 is fixed to cover and protect internal components. By the stem 101 and the cap 102, the package is configured.

On the mount 105, the driver chip 120 is mounted. The laser diode chip 110 is attached to a tip portion of the post 106 via a heatsink 107. On the top surface of the package, a glass window 103 is provided at a position corresponding to an optical path to let the laser beam emitted by the laser diode chip 110 pass therethrough. A plurality of leads 104 are provided to penetrate through the stem 101. The leads 104 are connected to the driver chip 120 by bonding wires 108.

As shown in FIG. 2, the laser diode chip 110 is mounted in the package such that an light emitting surface thereof faces the top surface of the package, and monitoring laser light emitted from an opposite side of the light emitting surface of the laser diode chip 110 proceeds to the driver chip 120. The laser diode chip 110 is connected to the driver chip 120 with bonding wires. The laser beam emitted by the laser diode ship 110 proceeds toward the outside of the laser diode 1 through the glass window 103.

As shown in FIG. 3, the driver chip 120 is mounted on the mount 105 such that the driver chip 120 is inclined with respect to the top surface of the mount 105 by a spacer 105a.

The driver chip 120 is a monolithic chip on which a driving circuit for the laser diode chip 110 and a photodiode 121 are integrally formed. The photodiode 121 is located on the driver chip 120 to receive the monitoring laser light emitted from the laser diode chip 110. Since the driver chip 120 is inclined with respect to the top surface of the mount 105, it is possible to prevent the monitoring laser light reflected from a right receiving surface of the photodiode 121 from being incident on the laser diode chip 110 again. Thus, a resonance phenomenon in the laser diode chip 110 is not affected by returning laser light (i.e., the reflected monitoring laser light) from the photodiode 121, by which stable operation of the laser diode chip 110 is secured.

FIG. 4 is a circuit diagram of the driver chip 120 and the laser diode chip 110. As described below, the driver chip 120 has the function of driving the laser diode chip 110 and the function of adjusting an output level of the laser diode chip 110.

The driver chip 120 includes a I/V (current to voltage) converter 122 which converts current generated by the photodiode 121 to a voltage level. That is, the voltage level made by the I/V converter 122 corresponds to the output level of the laser diode chip 110. The voltage level of the I/V converter 122 is compared with a reference voltage Vr by a comparator 123 to obtain a difference voltage.

The difference voltage is sampled by a sample-and-hold circuit 124 in accordance with the sample signal (indicated by “SAMPLE” in FIG. 4). The sample-and-hold circuit 124 has a capacitor C to hold the difference voltage from the I/V converter 123.

The difference voltage sampled by the sample-and-hold circuit 124 is then converted to current (i.e., driving current) for driving the laser diode chip 110. The driving current is on-off modulated by a switching circuit 126 in accordance with the data signal (indicated by “DATA” in FIG. 4). The laser diode chip 110 emits the laser beam of which output level corresponds to the driving current.

The data signal and the sample signal are supplied to the driver chip 120 from the controller 6. The capacitor C is connected to the driver chip 120 via the lead 104. Also, the reference voltage Vr is supplied to the driver chip 120 via the lead 104. The capacitor C and the reference voltage Vr (e.g., components for generating the Vr) are mounted on a circuit board (not shown in FIG. 1) on which the laser diode 1 is mounted.

The driver chip 120 operates to decrease the intensity of the driving current if the voltage level of the I/V converter 122 is higher than the reference voltage Vr, and to increase the intensity of the driving current if the voltage level of the I/V converter 122 is lower than the reference voltage. Thus, the output level of the laser diode chip 110 is kept at a constant level.

By inputting image data from the controller 6 to the driver chip 120, the on-off modulated laser beam in accordance with the image data is emitted by the laser diode 1 and is scanned on the photoconductive drum 5. Thus, a two dimensional image corresponding to the image data can be formed on the photoconductive drum 5.

Since the laser diode chip 110 and the driver chip 120 is connected to each other by the bonding wires, the length of wiring between the laser diode chip 110 and the driver chip 120 can be decreased extremely, by which the parasitic capacitance and the resistance of the wiring between the laser diode chip 110 and the driver chip 120 can be decreased extremely. Accordingly, the output performance of the laser beam can be improved. It becomes possible to drive the laser diode chip 110 under a suitable matching condition.

The laser diode 1 can be downsized. Further, use of the laser diode 1 enables a designer to design a compact laser scanning unit because the laser diode chip 110 and the driver chip 120 are integrally formed in the package of the laser diode 1.

Since the laser diode chip 110 is protected by the cap 102 and leads of the laser diode chip 110 are not directly connected to the leads 104 of the laser diode 1, direct handling of the laser diode chip 110 during the manufacturing process of the laser scanning unit 20 can be avoided, by which electrostatic discharge damage to the laser diode chip 110 can be avoided.

Second Embodiment

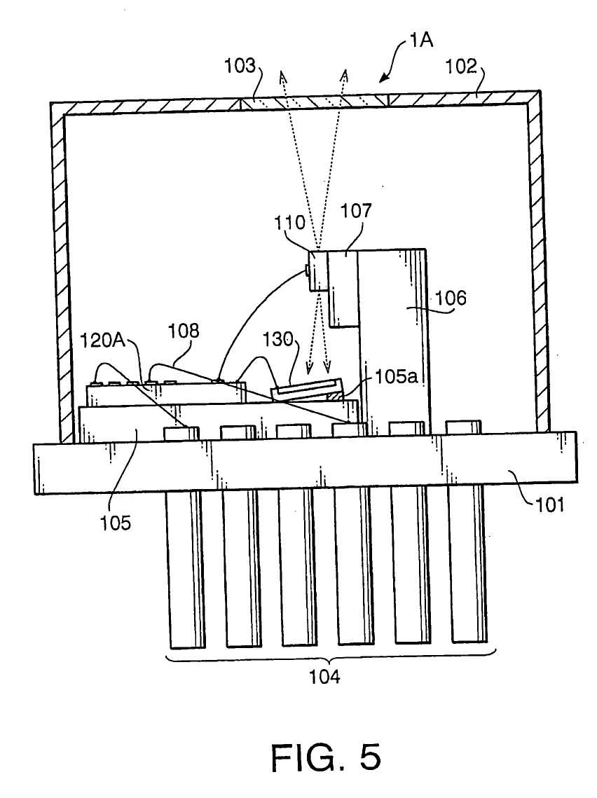

A laser diode 1A according to a second embodiment will be described. The laser diode 1A is configured as a variation of the laser diode 1 according to the first embodiment. Since an outward appearance of the laser diode 1A is the same as that of the laser diode 1, only a cross sectional view of the laser diode 1A (FIG. 5) is shown to describe the configuration of the laser diode 1A. FIG. 5 corresponds to the cross sectional view of FIG. 3 along the line A-A in FIG. 2. In FIG. 5, to elements, which are the same as those of the first embodiment, same reference numbers are assigned, and explanations thereof will not be repeated.

As shown in FIG. 5, in this embodiment, a photodiode chip 130 is mounted on the mount 105 as a discrete member. The photodiode chip 130 is connected to a driver chip 120A, which is also mounted on the mount 105, via bonding wires. The driver chip 120A includes the elements indicated in FIG. 4 excepting the photodiode 121.

As shown in FIG. 5, the photodiode chip 130 is inclined by the spacer 105a with respect to the top surface of the mount 105 so that the reflected monitoring laser light from a light receiving surface of the photodiode chip 130 does not proceed to the laser diode chip 110 for the reason above mentioned in the first embodiment.

Since the laser diode chip 110 and the driver chip 120A are connected to each other with the bonding wires, the length of wiring between the laser diode chip 110 and the driver chip 120A can be decreased extremely, by which the parasitic capacitance and the resistance of the wiring between the laser diode chip 110 and the driver chip 120A can be decreased extremely. Accordingly, the output performance of laser light can be improved. It becomes possible to drive the laser diode chip 110 under a suitable matching condition.

The laser diode 1A can be downsized. Further, use of the laser diode 1A enables a designer to design a compact laser scanning unit because the laser diode chip 110, the driver chip 120A and the photodiode chip 130 are integrally formed in the package of the laser diode 1A.

Since the laser diode chip 110 is protected by the cap 102 and leads of the laser diode chip 110 are not directly connected to the leads 104 of the laser diode 1A, direct handling of the laser diode chip 110 during the manufacturing process of the laser scanning unit 20 can be avoided, by which electrostatic discharge damage to the laser diode chip 110 can be avoided.

Further, according to the second embodiment, the photodiode chip 130 is formed as the discrete chip. Therefore, the photodiode chip 130 can be located at a suitable position for receiving the monitoring laser light from the laser diode chip 110. It is also possible to locate the photodiode chip 130 so that the length of wiring between the driver chip 120A and the photodiode chip 130 becomes minimum.

Third Embidiment

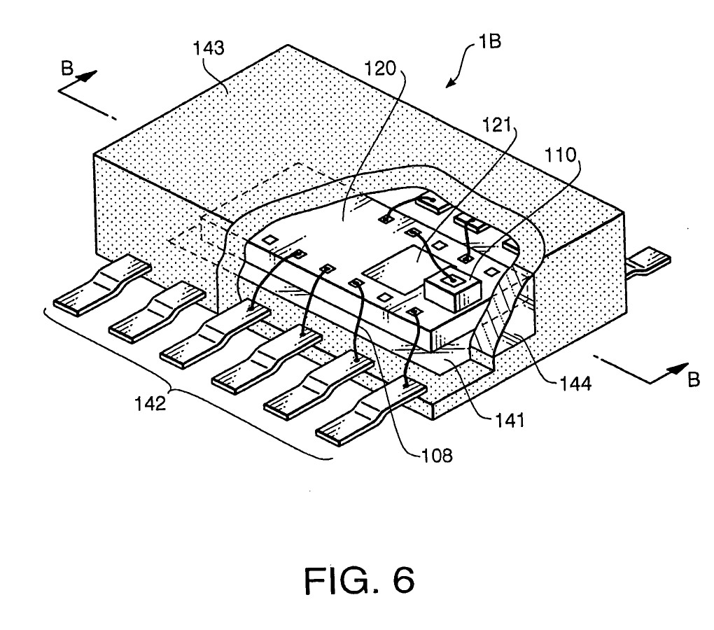

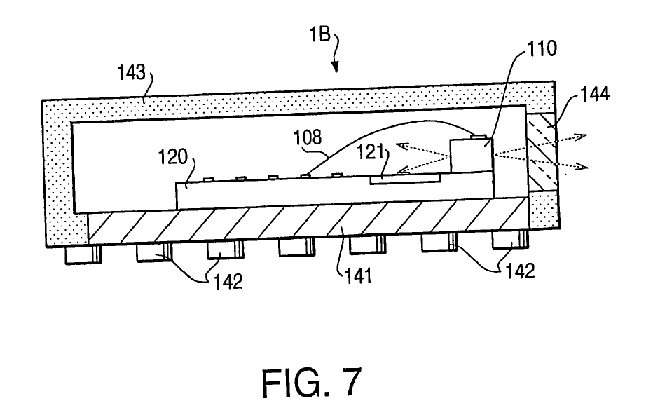

FIG. 6 is a perspective view of a laser diode 1B according to a third embodiment of the invention. In FIG. 6, a part of a package 143 is opened to show internal components of the laser diode 1B. FIG. 7 is a cross sectional view of the laser diode 1B along a line B-B in FIG. 6. The package 143 may be made of resin or ceramic. In FIGS. 6 and 7, to elements which are the same as those of the first embodiment, same reference numbers are assigned, and the explanations thereof will not be repeated.

As shown in FIGS. 6 and 7, the laser diode 1B is configured to be a surface-mount device. The laser diode 1B includes a base 141, which is a platy member made of metal, having leads 142 protruding from both of longitudinal side surfaces of the package 143.

On the base 141, the driver chip 120 integrally provided with the photo diode 121 is mounted. Further, the laser diode chip 110 is fixed on the driver chip 120 via a mounting member so that central axes of the laser beam and the monitoring laser light are in directions parallel with the top surface of the driver chip 120.

The laser diode chip 110 is connected to the driver chip 120 and to the leads 142 by bonding wires 108. As a part of the front surface of the package 143, a window 144 is formed with transparent resin so as to let the laser beam emitted by the laser diode chip 110 pass therethrough.

As shown in FIG. 7, the laser beam is emitted from the laser diode chip 110 toward the outside of the package 143 through the window 144. The monitoring laser light from the laser diode chip 110 is received by the photodiode 121.

Since the laser diode chip 110 and the driver chip 120 are connected to each other by the bonding wires, the length of wiring between the laser diode chip 110 and the driver chip 120 can be decreased extremely, by which the parasitic capacitance and the resistance of the wiring between the laser diode chip 110 and the driver chip 120 can be decreased extremely. Accordingly, the output performance of laser light can be improved. It becomes possible to drive the laser diode chip 110 under a suitable matching condition.

The laser diode 1B can be downsized. Further, use of the laser diode 1B enables a designer to design a compact laser scanning unit because the laser diode chip 110 and the driver chip 120 are integrally formed in the package of the laser diode 1B.

Since the laser diode chip 110 is protected by the package 143 and leads of the laser diode chip 110 are not directly connected to the leads 142 of the laser diode 1B, direct handling of the laser diode chip 110 during the manufacturing process of the laser scanning unit 20 can be avoided, by which electrostatic discharge damage to the laser diode chip 110 can be avoided.

Since the package 143 can be made of resin, the laser diode 1B is advantageous in cost reduction in comparison with the laser diodes 1 and 1A having the metal package. Further, since the laser diode 1B is the surface-mount device, productivity of the laser scanning unit can be enhanced.

Fourth Embodiment

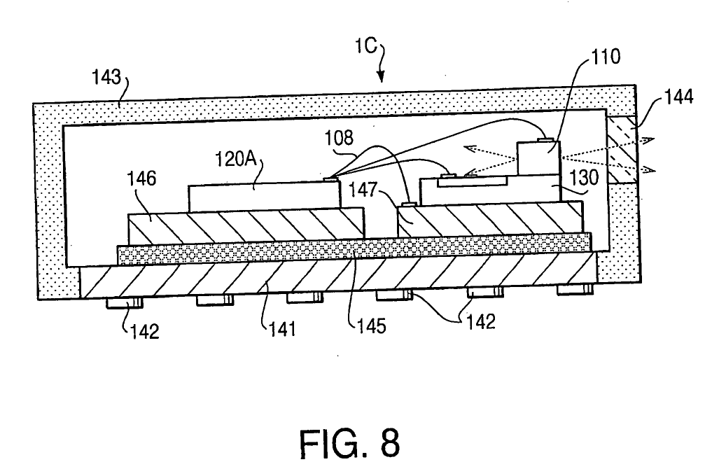

FIG. 8 is a cross sectional view of a laser diode 1C according to a fourth embodiment. The laser diode 1C is configured as a variation of the laser diode 1B of the third embodiment. That is, the laser diode 1C is a surface-mount device.

Since an outward appearance of the laser diode 1C is substantially the same as that of the laser diode 1B, only a cross sectional view of the laser diode 1C (FIG. 8) is shown to describe the configuration of the laser diode 1C. The cross sectional view of FIG. 8 corresponds to the cross sectional view of FIG. 7 along the line B-B in FIG. 6. In FIG. 8, to elements, which are the same as those of the above mentioned embodiments, same reference numbers are assigned, and explanations thereof will not be repeated.

As shown in FIG. 8, on the base 141, which is a lead frame having the leads 142, a thermal insulation plate 145 is mounted. A mount 146 and a mount 147 respectively functioning as heatsinks are mounted on the thermal insulation plate 145. Since the photodiode chip 130 is mounted on the mount 147, heat generated by the laser diode chip 110 is dissipated by the mount 147. Further, the photodiode chip 130 (i.e., the mount 147) is isolated from the driver chip 120A (i.e., the mount 146) by the thermal insulation plate 145, heat generated by the laser diode chip 110 is not transmitted to the driver chip 120A.

The laser diode chip 110 is mounted on the photodiode chip 130 so that the monitoring laser light is received by a light receiving surface of the photodiode chip 130 and the laser beam is outputted toward the outside of the package 143 through the window 144. Central axes of the laser beam and the monitoring laser light are in directions parallel with the top surface of the photodiode chip 130.

The laser diode chip 110 is connected to the driver chip 120A by the bonding wires 108. Also, the photodiode chip 130 is connected to the driver chip 120A by the bonding wires 108.

Since the laser diode chip 110, the driver chip 120A and the photodiode chip 130 are connected to each other by the bonding wires, the length of wiring between these components can be decreased extremely, by which the parasitic capacitance and the resistance of the wiring can be decreased extremely. Accordingly, the output performance of laser light can be improved. It becomes possible to drive the laser diode chip 110 under a suitable matching condition.

The laser diode 1C can be downsized. Further, use of the laser diode 1C enables a designer to design a compact laser scanning unit because the laser diode chip 110, the driver chip 120A and the photodiode chip 130 are integrally formed in the package of the laser diode 1C.

Since the laser diode chip 110 is protected by the package 143 and leads of the laser diode chip 110 are not directly connected to the leads 142 of the laser diode 1C, direct handling of the laser diode chip 110 during the manufacturing process of the laser scanning unit 20 can be avoided, by which electrostatic discharge damage to the laser diode chip 110 can be avoided.

Since the package 143 can be made of resin, the laser diode 1C is advantageous in cost reduction in comparison with the laser diodes 1 and 1A having the metal package. Further, since the laser diode 1C is the surface-mount device, productivity of the laser scanning unit can be enhanced.

Since the driver chip 120A and the photodiode chip 130 are mounted on different heatsinks (i.e., the mounts 146 and 147), heat generated by the laser diode chip 110 is not transmitted to the driver chip 120A, by which damage to the driver chip 120A by heat and deterioration of performance of the driver chip 120A by heat can be prevented.

Fifth Embodiment

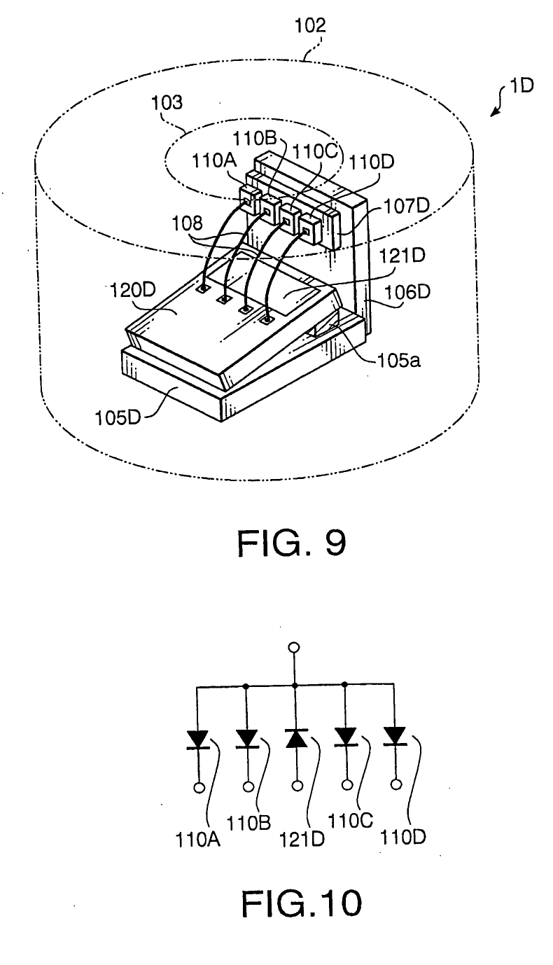

A laser diode 1D according to a fifth embodiment will be described. The laser diode 1D is configured as a variation of the laser diode 1 of the first embodiment. Since an outward appearance of the laser diode 1D is the same as that of the laser diode 1, an internal configuration of the laser diode 1D is explained using FIG. 9. FIG. 9 is a perspective view of the laser diode 1D illustrating the configuration inside of the cap 102. In FIG. 9, to elements, which are substantially the same as those of the first embodiment, same reference numbers are assigned, and explanations thereof will not be repeated.

As described below, the laser diode 1D is configured to emit a plurality of laser beams (four beams in this embodiment). The laser diode 1D is suitable for use in a multi-beam scanning optical system.

Similarly to the laser diode 1 according to the first embodiment, the laser diode 1D has a mount 105D on which a driver chip 120D (corresponding to the driver chip 120) is mounted. The driver chip 120D is inclined by the spacer 105a with respect to the top surface of the mount 105D. On the stem 101 (not shown in FIG. 9), a pole 106D is fixed.

The laser diode 1D has a plurality of laser diode chips 110A, 110B, 11oc and 110D which are aligned in a line and are attached to a tip portion of the pole 106D via a heatsink 107D. The laser diodes chips 110A, 110B, 110C and 110D are respectively connected to the driver chip 120D via bonding wires 108. Each of the laser diode chips 110A, 110B, 110C and 110D is mounted on the heatsink 107D such that a light emitting surface emitting monitoring laser light faces a photodiode 121D formed integrally in the driver chip 120D.

FIG. 10 is a circuit diagram with regard to the photodiode 121D and the laser diode chips 110A, 110B, 110C and 110D. The driver chip 120D has the driving function for driving the laser diode chips 110A, 110B, 110C and 110D independently. The photodiode 121D functions as a common photodiode for all of the laser diode chips 110A, 110B, 110C and 110D. The monitoring laser light emitted by each of the laser diode chips 110A, 110B, 110C and 110D is received by the photodiode 121D.

The driver chip 120D also has the function of adjusting an output level of each of the laser diode chips 110A, 110B, 110C and 110D by using an output of the photodiode 121D. That is, the driver chip 120D has a circuit similar to the circuit shown in FIG. 4 for each of the laser diode chips 110A, 110B, 110C and 110D.

It is understood that the laser diode 1D contributes to increasing printing speed when the laser diode 1D is employed in a printing device (i.e., in the multi-beam scanning optical system) using the laser diode 1D as a light source.

It is also understood that the laser diode 1D has substantially the same advantages as those of the first embodiment.

Although the present invention has been described in considerable detail with reference to certain preferred embodiments thereof, other embodiments are possible.

For example, various types of packages can be employed as packages of the laser diode although in the above mentioned embodiment only the metal and flat plastic packages are described by way of illustration. Locations of components (e.g., the laser diode chip and the driver chip) in the package are not limited to examples shown in the above mentioned embodiments.

The present disclosure relates to the subject matter contained in Japanese Patent Application No. 2003-345202, filed on Oct. 3, 2003, which is expressly incorporated herein by reference in its entirety.

1. A light emitting device, comprising:
a light emitting element that emits light;
a driving circuit that drives the light emitting element; and
a package that accommodates the light emitting element and the driving circuit.

2. The light emitting device according to claim 1, further comprising a light receiving element that receives the light emitted by the light emitting element, the light receiving element being accommodated in the package.

3. The light emitting device according to claim 2, wherein the driving circuit includes a processing circuit that processes a receiving signal generated by the light receiving element.

4. The light emitting device according to claim 3, wherein the driving circuit and the light receiving element are integrally formed on a single semiconductor chip.

5. The light emitting device according to claim 4, further comprising a mount on which the single semiconductor chip is mounted,
wherein the light emitted by the light emitting element includes monitoring light to be received by the light receiving element in the package,
wherein the mount is positioned in the package such that a central axis of the monitoring light is perpendicular to a top surface of the mount, and
wherein the single semiconductor chip is mounted on the mount such that the single semiconductor chip is inclined with respect to the top surface of the mount.

6. The light emitting device according to claim 4, wherein the light emitting element is mounted on the single semiconductor chip.

7. The light emitting device according to claim 3,
wherein the driving circuit is formed on a first semiconductor chip, and
wherein the light receiving element is formed on a second semiconductor chip located in the package separately from the first semiconductor chip.

8. The light emitting device according to claim 7, further comprising a mount on which the first semiconductor chip and the second semiconductor chip are mounted,
wherein the light emitted by the light emitting element includes monitoring light to be received by the light receiving element in the package,
wherein the mount is positioned in the package such that a central axis of the monitoring light is perpendicular to a top surface of the mount, and
wherein the second semiconductor chip is mounted on the mount such that the second semiconductor chip is inclined with respect to the top surface of the mount.

9. The light emitting device according to claim 7, wherein the light emitting element is mounted on the second semiconductor chip.

10. The light emitting device according to claim 9, further comprising a mount on which the first semiconductor chip and the second semiconductor chip are mounted.

11. The light emitting device according to claim 9, further comprising a thermal insulation plate on which the first semiconductor chip and the second semiconductor chip are mounted.

12. The light emitting device according to claim 2, wherein the light emitting element, the light receiving element and the driving circuit are located in the package separately with respect to each other.

13. The light emitting device according to claim 1, wherein the light emitting element includes a plurality of light emitting points.

14. The light emitting device according to claim 1, wherein the package is formed as a metal package.

15. The light emitting device according to claim 1, wherein the package is formed as a plastic package.

16. The light emitting device according to claim 1, wherein the package is formed as a surface mount type package.
